(19) United States
(12) Patent Application Publication
(10) Pub. No.: US 2025/0286012 A1
(43) Pub. Date: Sep. 11, 2025

(54) SEMICONDUCTOR PACKAGE HAVING A BALL-BOND INTERCONNECT STRUCTURE AND RELATED METHODS OF MANUFACTURING

(71) Applicant: Infineon Technologies AG, Neubiberg (DE)

(72) Inventors: Mohd Kahar Bajuri, Melaka (MY); Joel Feliciano Del Rosario, Malacca (MY); Emil Lamco Jocson, Malacca (MY); Hui Wen Goh, Melaka (MY); Julian Treu, München (DE)

(21) Appl. No.: 18/599,333

(22) Filed: Mar. 8, 2024

(51) Int. Cl. H01L 23/00

(52) U.S. Cl. CPC H01L 24/48; H01L 24/05; H01L 24/32; H01L 24/45; H01L 24/49; H01L 24/73; H01L 24/85; H01L 2224/05147; H01L 2224/32225; H01L 2224/45147; H01L 2224/4809; H01L 2224/48225; H01L 2224/48463; H01L 2224/49174; H01L 2224/73265; H01L 2224/85045; H01L 2924/10272; H01L 2924/1033; H01L 2924/1431

(57) ABSTRACT

A semiconductor package includes: a substrate; a plurality of leads; a semiconductor die attached to the substrate at a first side of the semiconductor die, the semiconductor die having a bond pad at a second side of the semiconductor die opposite the first side; and a ball-bond interconnect structure connecting the bond pad to a first lead of the plurality of leads. The ball-bond interconnect structure includes at least two levels of ball-bonded wire loops stacked on one another, and attached to one another at opposite ends of the stacked ball-bonded wire loops such that the at least two levels of stacked ball-bonded wire loops are electrically in parallel. Methods of manufacturing the semiconductor package are also described.

### BACKGROUND

Advancements in SiC (silicon carbide) and GaN (gallium nitride) technologies have yielded smaller bond pad sizes which are up to 30% smaller for higher current density, compared to Si (silicon) technology. Such small bond pads require a high power density interconnect within a small pad/lead area.

Thus, there is a need for an improved interconnect structure for semiconductor packages with small bond pad sizes.

### SUMMARY

According to an embodiment of a semiconductor package, the semiconductor package comprises: a substrate; a plurality of leads; a semiconductor die attached to the substrate at a first side of the semiconductor die, the semiconductor die having a bond pad at a second side of the semiconductor die opposite the first side; and a ball-bond interconnect structure connecting the bond pad to a first lead of the plurality of leads, wherein the ball-bond interconnect structure comprises at least two levels of ball-bonded wire loops stacked on one another, and attached to one another at opposite ends of the stacked ball-bonded wire loops such that the at least two levels of stacked ball-bonded wire loops are electrically in parallel, wherein the at least two levels of stacked wire bond loops comprises: a first ball-bonded wire loop connected between the bond pad and the first lead, the first ball-bonded wire loop comprising a ball end attached to one of the bond pad or the first lead, a tail end attached to the other one of the bond pad or the first lead, and a wire section that is compressed into the ball end of the first ball-bonded wire loop and flattened; and a second ball-bonded wire loop stacked on the first ball-bonded wire loop, the second ball-bonded wire loop comprising a ball end attached to the tail end of the first ball-bonded wire loop, a tail end attached to the ball end of the first ball-bonded wire loop, and a wire section that is compressed into the ball end of the second ball-bonded wire loop and flattened.

According to an embodiment of a method of manufacturing a semiconductor package, the method comprises: attaching a first side of a semiconductor die to a substrate, the semiconductor die having a bond pad at a second side of the semiconductor die opposite the first side; and forming a ball-bond interconnect structure that connects the bond pad to a first lead, the ball-bond interconnect structure comprising at least two levels of ball-bonded wire loops stacked on one another, and attached to one another at opposite ends of the stacked ball-bonded wire loops such that the at least two levels of stacked ball-bonded wire loops are electrically in parallel, wherein forming the ball-bond interconnect structure comprises: connecting a first ball-bonded wire loop between the bond pad and the first lead, the first ball-bonded wire loop comprising a ball end attached to one of the bond pad or the first lead, a tail end attached to the other one of the bond pad or the first lead, and a wire section that is compressed into the ball end of the first ball-bonded wire loop and flattened; and vertically stacking a second ball-bonded wire loop on the first ball-bonded wire loop, the second ball-bonded wire loop comprising a ball end attached to the tail end of the first ball-bonded wire loop, a tail end attached to the ball end of the first ball-bonded wire loop, and a wire section that is compressed into the ball end of the second ball-bonded wire loop and flattened.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a top plan view of a semiconductor package that includes a multi-level ball-bond interconnect structure for connecting a bond pad of the die to a lead of a package that includes the die.

FIGS. 2A and 2B illustrate respective side perspective views of the multi-level ball-bond interconnect structure during different stages of manufacturing.

FIG. 3 illustrates an embodiment of forming a ball-bonded wire loop included in the lowermost level of ball-bonded wire loops of the multi-level ball-bond interconnect structure.

FIG. 4 illustrates an embodiment of attaching a ball end of an upper ball-bonded wire loop to a tail end of a lower ball-bonded wire loop of the multi-level ball-bond interconnect structure.

FIG. 5 illustrates an embodiment of attaching a bond wire that extends from a stitch of the upper ball-bonded wire loop to a ball end of the lower ball-bonded wire loop.

### DETAILED DESCRIPTION

The embodiments described herein provide a multi-level ball-bond interconnect structure for connecting a bond pad of a semiconductor die (chip) to a lead of a package that includes the semiconductor die. The multi-level ball-bond interconnect structure has at least two levels of ball-bonded wire loops stacked on one another in a direction perpendicular to the die bond pad. The at least two levels of ball-bonded wire loops are attached to one another at opposite ends of the stacked ball-bonded wire loops such that the at least two levels of stacked ball-bonded wire loops are electrically in parallel. The multi-level ball-bond interconnect structure supports higher current density for smaller bond pad footprints and accommodates a wide range of wire size diameters (e.g., 25 to 75 μm or larger) and materials (e.g., Cu, Au, etc.). The multi-level ball-bond interconnect structure has several advantages over stacked wedge bonding, including higher throughout (e.g., 2×-3× faster units per hour), does not require a thicker bond pad, lower cost (e.g., 3× more cost effective), and wider applicability since ball bonding technology is used in over 90% of semiconductor packaging compared to wedge bonding technology.

Described next, with reference to the figures, are exemplary embodiments of the multi-level ball-bond interconnect structure and related methods of manufacturing.

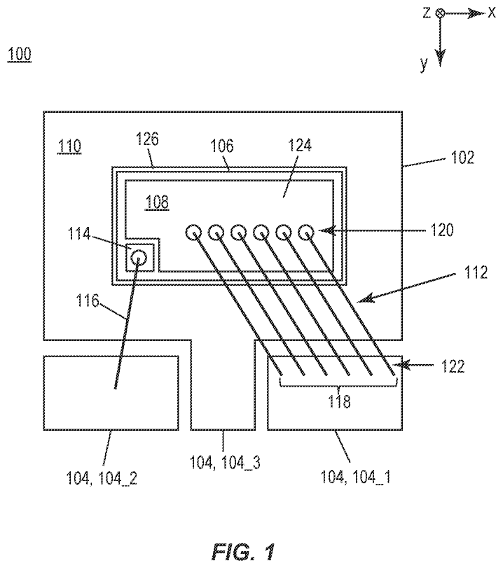

FIG. 1 illustrates a top plan view of a semiconductor package 100, prior to molding. The semiconductor package 100 includes a substrate 102, leads 104, and a semiconductor die 106 attached to the substrate 102 at a back side of the semiconductor die 106. The semiconductor die 106 has a first bond pad 108 at the front side of the semiconductor die 106 which is opposite the back side.

The semiconductor die 106 may be a logic die such as a processor die, memory die, etc., a power semiconductor die such as a power transistor die, a power diode die, a half bridge die, etc., or a die that combines logic and power devices on the same semiconductor substrate. In one embodiment, the semiconductor die 106 is a vertical semiconductor die having a primary current path between the bond pad 108 at the die front side and a bond pad (out of view) at the die back side. Examples of vertical power semiconductor dies include but are not limited to power Si MOSFETs (metal-oxide-semiconductor field-effect transistors), IGBTs (insulated-gate bipolar transistors), SiC MOSFETs, GaN HEMTs (high-electron mobility transistors), etc.

More than one semiconductor die 106 may be attached to the same or different substrate 102 such that the semiconductor package 100 may include one or more semiconductor dies 106. For example, the semiconductor package 100 may be a discrete in that the package 100 includes a single semiconductor die 106 such as a low-side or high-side power transistor die. In another example, the semiconductor package 100 may include one or more low-side power transistor dies in parallel and one or more high-side power transistor dies in parallel to form a half bridge. A gate driver (not shown) for each semiconductor die 106 also may be included in the semiconductor package 100.

The substrate 102 to which at least one semiconductor die 106 is attached may be a lead frame. For example, the semiconductor die 106 may be attached to a die paddle 110 of the lead frame and the package leads 104 may be part of the lead frame. The lead frame features (e.g., leads 104, die paddle 110, etc.) may be defined by etching, stamping, etc. of a metallic sheet such as a Cu (copper) sheet.

The semiconductor package 100 also includes a multi-level ball-bond interconnect structure 112 that connects the first bond pad 108 of the semiconductor die 106 to a first lead 104_1 of the package leads 104. For example, in the case of a vertical power transistor die, the first bond pad 108 may be a source pad and the multi-level ball-bond interconnect structure 112 may connect the source pad 108 to a source lead 104_1 of the package. Further in the case of a vertical power transistor die, a gate pad 114 may be disposed at the same side of the semiconductor die 106 as the source pad 108 and may be electrically connected to another lead 104_2, e.g., by at least bond wire 116. In the case of a lead frame as the substrate 102, the die paddle 110 may form one of the package leads 104_3.

The ball-bond interconnect structure 112 is multi-level in that the ball-bond interconnect structure 112 includes at least two levels of ball-bonded wire loops 118 stacked on one another in a direction (z direction in FIG. 1) perpendicular to the front side of the semiconductor die 106. The at least two levels of ball-bonded wire loops 118 are attached to one another at opposite ends 120, 122 of the stacked ball-bonded wire loops 118 such that the at least two levels of stacked ball-bonded wire loops 118 are electrically in parallel to support higher current density. The multi-level ball-bond interconnect structure 112 may be particularly advantageous for smaller bond pad footprints having a relatively high current density, e.g., in the case of the semiconductor die 106 being a SiC or GaN die. In the case of a SiC or GaN, the semiconductor die 106 may have an area less than 2 mm² and/or a current density greater than 4.5 A/mm² and/or be attached to the substrate 102 by lead-free solder 126. The multi-level ball-bond interconnect structure 112 also may be used with larger bond pad footprints, e.g., in the case of the semiconductor die 106 being made from Si.

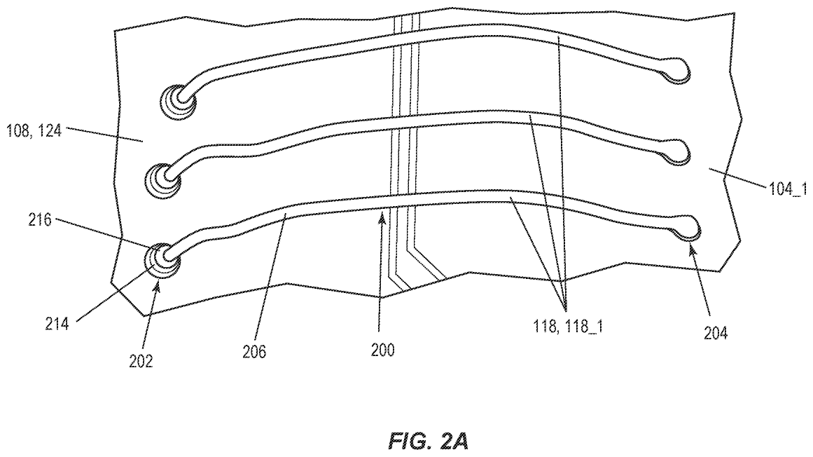

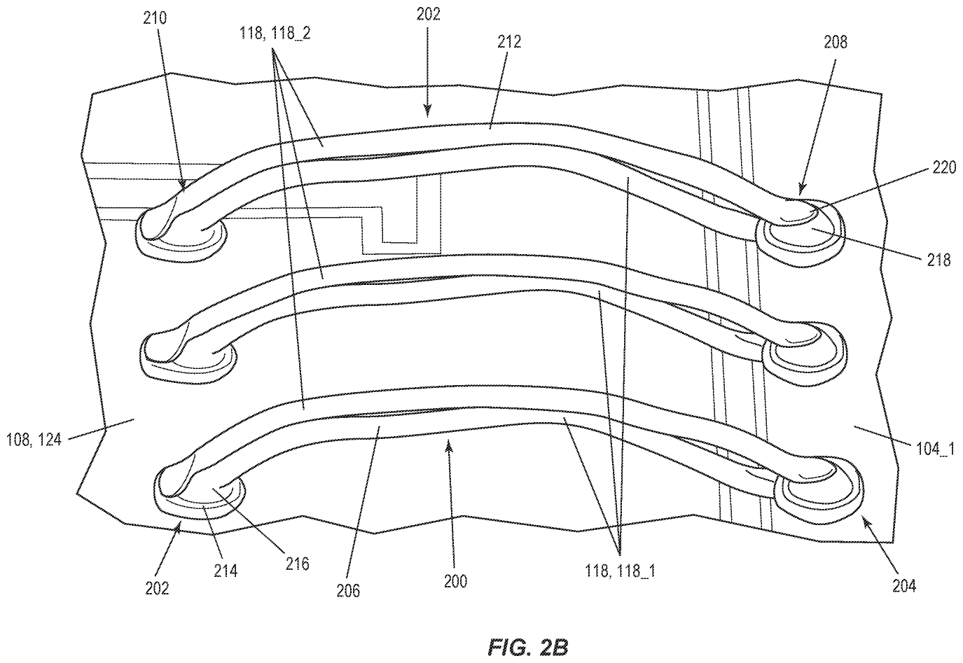

FIGS. 2A and 2B illustrate respective side perspective views of the multi-level ball-bond interconnect structure 112 during different stages of manufacturing. FIG. 2A shows the multi-level ball-bond interconnect structure 112 after a first (lowermost) level 200 of ball-bonded wire loops 118 is formed, and FIG. 2B shows the ball-bond interconnect structure 112 after a second level 202 of ball-bonded wire loops 118 is vertically stacked on the lowermost level 200 of ball-bonded wire loops 118.

The lowermost level 200 of ball-bonded wire loops 118 includes a plurality of first ball-bonded wire loops 118_1 connected in parallel between the die bond pad 108 and the corresponding package lead 104_1. Three (3) first ball-bonded wire loops 118_1 are visible in the partial views of FIGS. 2A and 2B. However, the lowermost level 200 of ball-bonded wire loops 118 may include two (2), three (3) or more first ball-bonded wire loops 118_1 connected in parallel between the die bond pad 108 and the corresponding package lead 104_1. Each first ball-bonded wire loop 118_1 has a ball end 202 attached to one of the die bond pad 108 or the package lead 104_1, a tail (stitch) end 204 attached to the other one of the die bond pad 108 or package lead 104_1, and a wire section 216 that is compressed into the ball end 202 and flattened.

The second level 202 of ball-bonded wire loops 118 includes a plurality of second ball-bonded wire loops 118_2 stacked on the plurality of first ball-bonded wire loops 118_1. Three (3) second ball-bonded wire loops 118_2 are visible in the partial view of FIG. 2B. However, the second level 202 of ball-bonded wire loops 118 may include two (2), three (3) or more second ball-bonded wire loops 118_2 stacked on the plurality of first ball-bonded wire loops 118_1. In one embodiment, the second level 202 of ball-bonded wire loops 118 includes the same number of ball-bonded wire loops 118 as the first level 200 of ball-bonded wire loops 118. However, the second level 202 of ball-bonded wire loops 118 may include fewer ball-bonded wire loops 118 than the first level 200 of ball-bonded wire loops 118, e.g., one-half, one-third, etc.

Each second ball-bonded wire loop 118_2 has a ball end 208 attached to the tail end 204 of a corresponding one of the first ball-bonded wire loops 118_1 and a tail end 210 attached to the ball end 202 of the corresponding first ball-bonded wire loop 118_1. Each second ball-bonded wire loop 118_2 also has a wire section 212 that is folded in a lateral (e.g., x) direction and extends between the ball end 210 and the tail end 208 of the second ball-bonded wire loop 118_2.

As shown in FIG. 2A, the ball end 202 of each first ball-bonded wire loop 118_1 has a ball bump 214 attached to one of the die bond pad 108 or the package lead 104_1 and a wire section 216 that is compressed into the ball bump 214 and flattened as part of a wire folding process. As shown in FIG. 2B, the ball end 208 of each second ball-bonded wire loop 118_2 has a ball bump 218 attached to the tail end 204 of the corresponding first ball-bonded wire loop 118_1 and a stitch 220 on the ball bump 218 of the second ball-bonded wire loop 118_2. The ball bump 218 of each second ball-bonded wire loop 118_2 is first bonded to the tail end 204 of the corresponding first ball-bonded wire loop 118_1, and then the stitch 220 is formed on top of the ball bump 218 as part of a wire folding process. The tail end 210 of each second ball-bonded wire loop 118_2 is attached to the stitch 216 and the ball bump 214 of the corresponding first ball-bonded wire loop 118_1.

In one embodiment, the outermost layer 124 of the die bond pad 108 to which the multi-level ball-bond interconnect structure 112 is attached comprises copper and the plurality of first ball-bonded wire loops 118_1 and the plurality of second ball-bonded wire loops 118_2 each comprise copper. In another embodiment, the outermost layer 124 of the die bond pad 108 to which the multi-level ball-bond interconnect structure 112 is attached comprises gold and the plurality of first ball-bonded wire loops 118_1 and the plurality of second ball-bonded wire loops 118_2 each comprise gold. Other monometallic systems or a bimetallic system may be used.

Separately or in combination, the plurality of first ball-bonded wire loops 118_1 and the plurality of second ball-bonded wire loops 118_2 each have a diameter in a range of 25 μm to 75 μm. Separately or in combination, the plurality of first ball-bonded wire loops 118_1 has a first diameter and the plurality of second ball-bonded wire loops 118_2 has a second diameter different than the first diameter such that the plurality of first ball-bonded wire loops 118_1 may be thinner or thicker than the plurality of second ball-bonded wire loops 118_2.

Two (2) levels 200, 202 of stacked ball-bonded wire loops 118 are shown in FIG. 2B. However, this is just an example. The multi-level ball-bond interconnect structure 112 may have more than two (2) levels of ball-bonded wire loops 118 stacked on one another in the vertical direction, where each overlying level of ball-bonded wire loops 118 runs in the opposite direction as the underlying level of ball-bonded wire loops 118 such that interleaved stacks of ball and tail end bonds are formed at both ends of the multi-level ball-bond interconnect structure 112. For example, a plurality of third ball-bonded wire loops (not shown in FIGS. 2A and 2B) may be stacked on the plurality of second ball-bonded wire loops 118_2, where each third ball-bonded wire loop has a ball end attached to the tail end 210 of a corresponding one of the second ball-bonded wire loops 118_2, a tail end attached to the ball end 208 of the corresponding second ball-bonded wire loop 118_2, and a wire section that is compressed into the ball end of the wire loop and flattened.

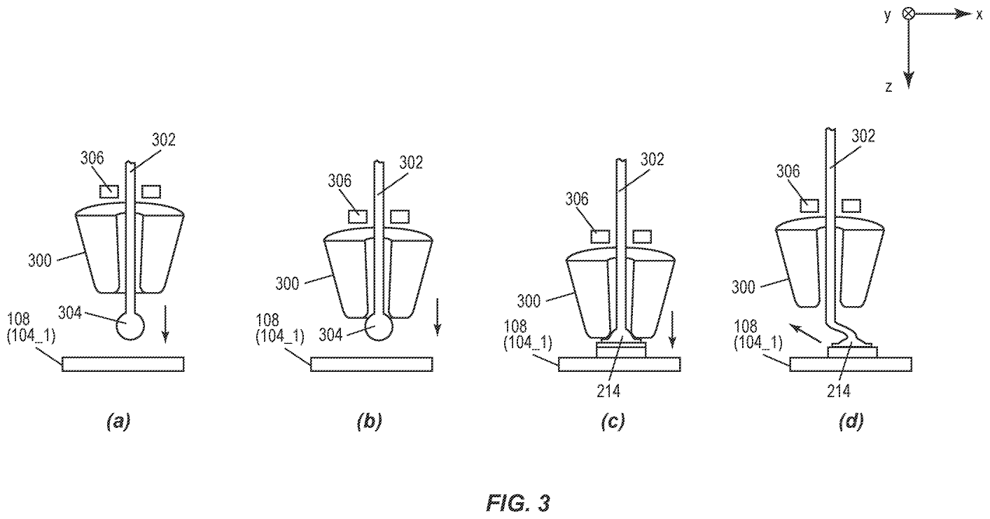

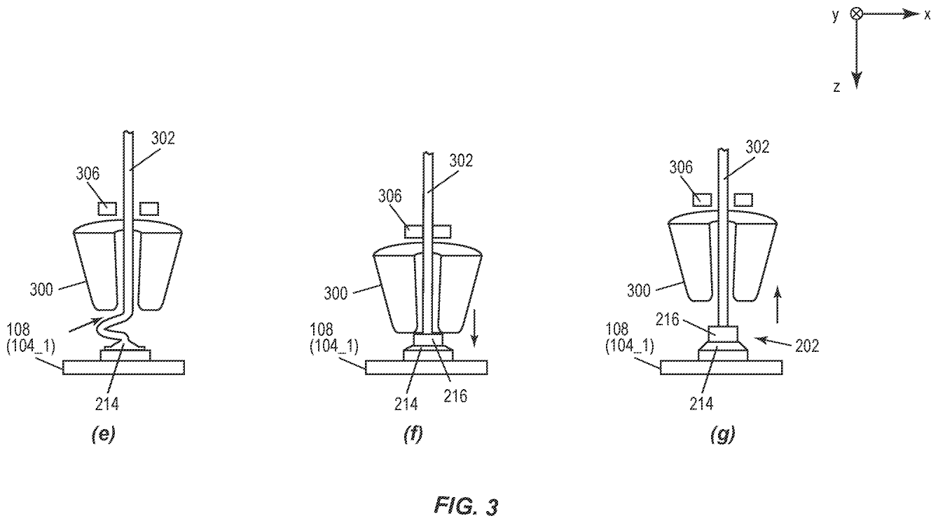

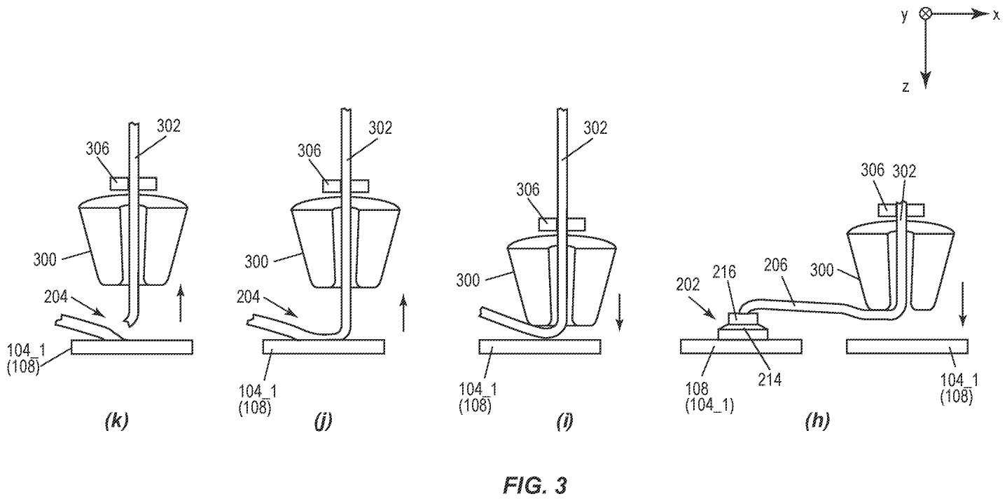

FIG. 3 illustrates an embodiment of forming one of the first ball-bonded wire loop 118_1 included in the lowermost level 200 of ball-bonded wire loops 118. The process illustrated in FIG. 3 may be repeated one or more times to form two (2) or more first ball-bonded wire loops 118_1 that are connected in parallel between two (2) bond sites.

In step (a) of FIG. 3, an electrical flame off (EFO) process is performed using a capillary 300 threaded with a bond wire 302 to form a free air ball 304 at the end of the bond wire 302.

In step (b) of FIG. 3, the capillary 300 captures the free air ball 304 with the capillary clamp 306 released and moves in the z direction to the first bond site which may be the die bond pad 108 or the corresponding package lead 104_1.

In step (c) of FIG. 3, force and/or ultrasonic energy are applied to form the ball bump 214 of a first ball-bonded wire loop 118_1 at the first bond site such that the ball bump 214 is attached to one of the die bond pad 106 or the corresponding package lead 104_1. The second bond site is the other one of the die bond pad 106 or the package lead 104_1 and to which the ball bump 214 is not attached.

Steps (d) and (e) of FIG. 3 involve a wire folding process during which the capillary 300 is moved in the z direction away from the first bond site and changes lateral (e.g., x or y) direction, as indicated by the angled arrows, to fold the bond wire 302.

In step (f) of FIG. 3, the clamp 306 closes and the capillary 300 moves downwards in the z direction towards the first bond site and compresses the folded section in the bond wire 302 (e.g. z or s-shaped fold) onto the previously formed ball bump 214. This folding and compressing creates a flattened area that allows for the stacking of multiple wire loops while mitigating bonding related issues. For example, the stitch of a second ball-bonded wire loop stacked on the first ball-bonded wire loop is likely to be malformed if the capillary is directly pressed onto the rounded ball bump without the creation of a flattened bonding area over the ball bump 304 using the folding and compressing steps.

In step (g) of FIG. 3, the capillary 300 moves in the z direction away from the first bond site with the clamp 306 released as part of a wire looping process. The flattening of the wire loop also enables having a lower loop angle and accordingly making the stacking of multiple wire loop layers possible. The wire looping process further involves moving the capillary 300 with the clamp 306 released in a lateral (e.g., x) direction to the second bond site, folding the bond wire 302 in the lateral direction and defining the length of a folded wire section 206 that extends between the ball end 202 and the tail end 204 of the first ball-bonded wire loop 118_1.

In step (h) of FIG. 3, the clamp 306 is engaged and the capillary 300 moves in the z direction to the second bond site.

In step (i) of FIG. 3, the clamp 306 is released and force and/or ultrasonic energy are applied to attach the bond wire 302 that extends from the stitch 216 to the second bond site.

In step (j) of FIG. 3, the capillary 300 moves away from the second bond site in the z direction with the clamp 306 released.

In step (k) of FIG. 3, the clamp 306 is engaged and the capillary 300 continues to move away from the second bond site in the z direction, severing the bond wire 302 to form the tail (stitch) end 204 of the first ball-bonded wire loop 118_1 and complete the first ball-bonded wire loop 118_1.

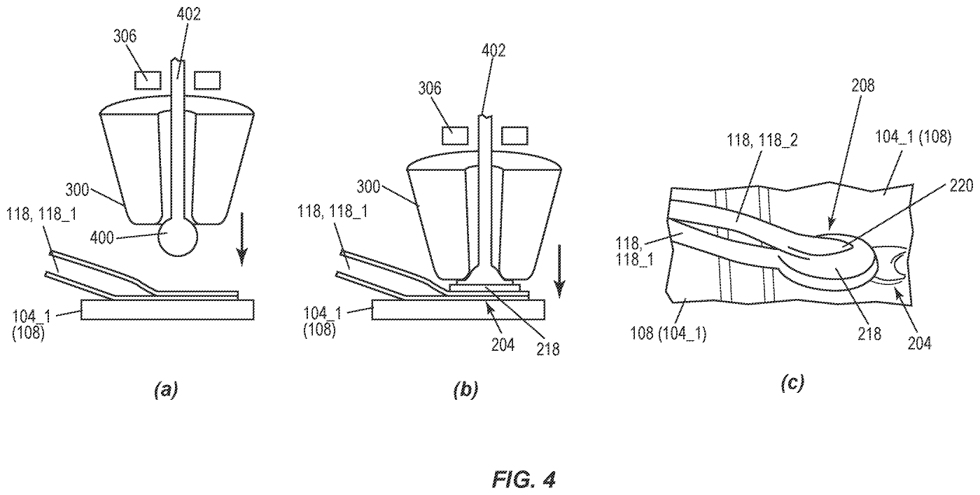

FIG. 4 illustrates an embodiment of attaching the ball end 208 of a second ball-bonded wire loop 118_2 to the tail end 204 of one of the first ball-bonded wire loops 118_1. The process illustrated in FIG. 4 may be repeated for each first ball-bonded wire loop 118_1 in the lowermost level 200 of ball-bonded wire loops 118. The process illustrated in FIG. 4 may be repeated for each additional level of stacked ball-bonded wire loops 118, but changing direction for each additional level such that the ball end of each new ball-bonded wire loop 118 being formed is bonded to the tail end of the previously formed ball-bonded wire loop 118.

In step (a) of FIG. 4, a free air ball 400 has already been formed at the end of a bond wire 402 fed through the capillary 300 and the capillary 300 moves in the z direction with the clamp 306 released towards the tail end 204 of the corresponding first ball-bonded wire loop 118_1. The free air ball 400 may be formed as explained above in connection with step (a) of FIG. 3.

In step (b) of FIG. 4, force and/or ultrasonic energy are applied to form the ball bump 218 of the second ball-bonded wire loop 118_2. The ball bump 218 of the second ball-bonded wire loop 118_2 is attached to the tail end 204 of the corresponding first ball-bonded wire loop 118_1.

In step (c) of FIG. 4, the bond wire 402 is folded in a lateral (e.g., x) direction and force and/or ultrasonic energy are applied to form the stitch 220 on the ball bump 218 of the second ball-bonded wire loop 118_2, e.g., as explained above in connection with steps (d) through (f) of FIG. 3. The capillary 300 is then moved as part of a wire looping process that involves vertical and lateral movement to bend or loop the bond wire 402 to the second bond site, e.g., as explained above in connection with steps (g) and (h) of FIG. 3.

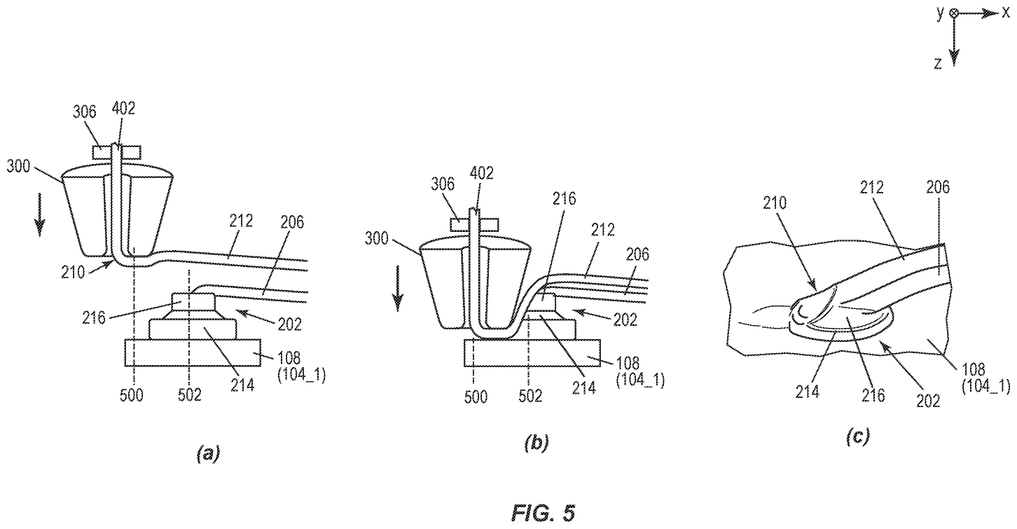

FIG. 5 illustrates an embodiment of attaching the bond wire 402 that extends from the stitch 220 of the second ball-bonded wire loop 118_2 to the ball end 202 of the corresponding first ball-bonded wire loop 118_1. The process illustrated in FIG. 5 may be repeated for each first ball-bonded wire loop 118_1 in the lowermost level 200 of ball-bonded wire loops 118. The process illustrated in FIG. 5 may be repeated for each additional level of stacked ball-bonded wire loops 118, but changing direction for each additional level such that the tail end of each ball-bonded wire loop 118 being formed is bonded to the ball end of the underlying ball-bonded wire loop 118.

In step (a) of FIG. 5, the capillary 300 is moved such that in a longitudinal (lengthwise) direction (x direction in FIG. 5) of the ball-bond interconnect structure 112, a center point 500 of the tail end 210 of the second ball-bonded wire loop 118_2 is off-centered in the longitudinal direction from the center point 504 of the ball bump 214 of the corresponding first ball-bonded wire loop 118_1. Such longitudinal off-centering allows for a more planar stacking at the ends 202, 210 of the stacked wire loops 118_1, 118_2. The positioning of the capillary 300 also defines the length of the folded wire section 212 that extends between the ball end 208 and the tail end 210 of the second ball-bonded wire loop 118_2.

In step (b) of FIG. 5, the capillary clamp 306 is released and force and/or ultrasonic energy are applied to attach the bond wire 402 that extends from the stitch 220 of the second ball-bonded wire loop 118_2 to the ball end 202 of the corresponding first ball-bonded wire loop 118_1.

In step (c) of FIG. 5, the bond wire 402 is severed to form the tail end 210 of the second ball-bonded wire loop 118_2 and complete the second ball-bonded wire loop 118_2. The tail end 210 of the second ball-bonded wire loop 118_2 is attached to the ball end 202 of the corresponding first ball-bonded wire loop 118_2.

The process illustrated in FIGS. 4 and 5 may be repeated for each additional level of ball-bonded wire loops 118 that form the ball-bond interconnect structure 112, by stacking a desired number of ball-bonded wire loops 118 on the next lowermost level of ball-bonded wire loops 118. Each ball-bonded wire loop 118 in the newest level of ball-bonded wire loops 118 has a ball end attached to the tail end of the corresponding ball-bonded wire loop 118 in the next lowermost level of ball-bonded wire loops 118, a tail end attached to the ball end of the corresponding ball-bonded wire loop, and a wire section that is compressed into the ball end of the new ball-bonded wire loop and flattened.

Although the present disclosure is not so limited, the following numbered examples demonstrate one or more aspects of the disclosure.

Example 1. A semiconductor package, comprising: a substrate; a plurality of leads; a semiconductor die attached to the substrate at a first side of the semiconductor die, the semiconductor die having a bond pad at a second side of the semiconductor die opposite the first side; and a ball-bond interconnect structure connecting the bond pad to a first lead of the plurality of leads, wherein the ball-bond interconnect structure comprises at least two levels of ball-bonded wire loops stacked on one another, and attached to one another at opposite ends of the stacked ball-bonded wire loops such that the at least two levels of stacked ball-bonded wire loops are electrically in parallel, wherein the at least two levels of stacked wire bond loops comprises: a first ball-bonded wire loop connected between the bond pad and the first lead, the first ball-bonded wire loop comprising a ball end attached to one of the bond pad or the first lead, a tail end attached to the other one of the bond pad or the first lead, and a wire section that is compressed into the ball end of the first ball-bonded wire loop and flattened; and a second ball-bonded wire loop stacked on the first ball-bonded wire loop, the second ball-bonded wire loop comprising a ball end attached to the tail end of the first ball-bonded wire loop, a tail end attached to the ball end of the first ball-bonded wire loop, and a wire section that is compressed into the ball end of the second ball-bonded wire loop and flattened.

Example 2. The semiconductor package of example 1, wherein the ball end of the first ball-bonded wire loop comprises a ball bump attached to one of the bond pad or the first lead and a stitch on the ball bump, wherein the ball end of the second ball-bonded wire loop comprises a ball bump attached to the tail end of the first ball-bonded wire loop and a stitch on the ball bump of the second ball-bonded wire loop, and wherein the tail end of the second ball-bonded wire loop is attached to the stitch and the ball bump of the first ball-bonded wire loop.

Example 3. The semiconductor package of example 1 or 2, wherein the at least two levels of stacked wire bond loops comprises: a third ball-bonded wire loop stacked on the second ball-bonded wire loop, the third ball-bonded wire loop comprising a ball end attached to the tail end of the second ball-bonded wire loop, a tail end attached to the ball end of the second ball-bonded wire loop, and a wire section that is compressed into the ball end of the third ball-bonded wire loop and flattened.

Example 4. The semiconductor package of any of examples 1 through 3, wherein the semiconductor die is a SiC or GaN die.

Example 5. The semiconductor package of example 4, wherein an outermost layer of the bond pad comprises copper, and wherein the first ball-bonded wire loop and the second ball-bonded wire loop both comprise copper.

Example 6. The semiconductor package of example 5, wherein the first ball-bonded wire loop and the second ball-bonded wire loop both have a diameter in a range of 25 μm to 75 μm.

Example 7. The semiconductor package of example 5 or 6, wherein the first ball-bonded wire loop has a first diameter, and wherein the second ball-bonded wire loop has a second diameter different than the first diameter.

Example 8. The semiconductor package of any of examples 5 through 7, wherein the semiconductor die is attached to the substrate by lead-free solder.

Example 9. The semiconductor package of any of examples 4 through 8, wherein the semiconductor die has an area less than 2 mm².

Example 10. The semiconductor package of example 9, wherein the semiconductor die has a current density greater than 4.5 A/mm².

Example 11. A method of manufacturing a semiconductor package, the method comprising: attaching a first side of a semiconductor die to a substrate, the semiconductor die having a bond pad at a second side of the semiconductor die opposite the first side; and forming a ball-bond interconnect structure that connects the bond pad to a first lead, the ball-bond interconnect structure comprising at least two levels of ball-bonded wire loops stacked on one another, and attached to one another at opposite ends of the stacked ball-bonded wire loops such that the at least two levels of stacked ball-bonded wire loops are electrically in parallel, wherein forming the ball-bond interconnect structure comprises: connecting a first ball-bonded wire loop between the bond pad and the first lead, the first ball-bonded wire loop comprising a ball end attached to one of the bond pad or the first lead, a tail end attached to the other one of the bond pad or the first lead, and a wire section that is compressed into the ball end of the first ball-bonded wire loop and flattened; and vertically stacking a second ball-bonded wire loop on the first ball-bonded wire loop, the second ball-bonded wire loop comprising a ball end attached to the tail end of the first ball-bonded wire loop, a tail end attached to the ball end of the first ball-bonded wire loop, and a wire section that is compressed into the ball end of the second ball-bonded wire loop and flattened.

Example 12. The method of example 11, wherein connecting the first ball-bonded wire loop between the bond pad and the first lead comprises: attaching a first ball bump to one of the bond pad or the first lead; forming a first stitch on the first ball bump; attaching a first wire that extends from the first stitch to the other one of the bond pad or the first lead; and severing the first wire to form the tail end of the first ball-bonded wire loop, wherein vertically stacking the second ball-bonded wire loop on the first ball-bonded wire loop comprises: attaching a second ball bump to the tail end of the first ball-bonded wire loop; forming a second stitch on the second ball bump; attaching a second wire that extends from the second stitch to the ball end of the first ball-bonded wire loop; and severing the second wire to form the tail end of the second ball-bonded wire loop.

Example 13. The method of example 12, wherein attaching the second wire that extends from the second stitch of the second ball-bonded wire loop to the ball end of the first ball-bonded wire loop comprises: in a longitudinal direction of the ball-bond interconnect structure, offsetting a center point of the tail end of the second ball-bonded wire loop from a center point of the first ball bump of the first ball-bonded wire loop.

Example 14. The method of any of examples 11 through 13, wherein forming the ball-bond interconnect structure comprises: stacking a third ball-bonded wire loop on the second ball-bonded wire loop, the third ball-bonded wire loop comprising a ball end attached to the tail end of the second ball-bonded wire loop, a tail end attached to the ball end of the second ball-bonded wire loop, and a wire section that is compressed into the ball end of the third ball-bonded wire loop and flattened.

Example 15. The method of any of examples 11 through 14, wherein the semiconductor die is a SiC or GaN die.

Example 16. The method of example 15, wherein an outermost layer of the bond pad comprises copper, and wherein the first ball-bonded wire loop and the second ball-bonded wire loop both comprise copper.

Example 17. The method of example 16, wherein the first ball-bonded wire loop and the second ball-bonded wire loop both have a diameter in a range of 25 μm to 75 μm.

Example 18. The method of any of examples 15 through 17, wherein attaching the first side of the semiconductor die to the substrate comprises: soldering the first side of the semiconductor die to the substrate using lead-free solder.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor package, comprising:
a substrate;
a plurality of leads;
a semiconductor die attached to the substrate at a first side of the semiconductor die, the semiconductor die having a bond pad at a second side of the semiconductor die opposite the first side; and
a ball-bond interconnect structure connecting the bond pad to a first lead of the plurality of leads,
wherein the ball-bond interconnect structure comprises at least two levels of ball-bonded wire loops stacked on one another, and attached to one another at opposite ends of the stacked ball-bonded wire loops such that the at least two levels of stacked ball-bonded wire loops are electrically in parallel,
wherein the at least two levels of stacked wire bond loops comprises:
a first ball-bonded wire loop connected between the bond pad and the first lead, the first ball-bonded wire loop comprising a ball end attached to one of the bond pad or the first lead, a tail end attached to the other one of the bond pad or the first lead, and a wire section that is compressed into the ball end of the first ball-bonded wire loop and flattened; and
a second ball-bonded wire loop stacked on the first ball-bonded wire loop, the second ball-bonded wire loop comprising a ball end attached to the tail end of the first ball-bonded wire loop, a tail end attached to the ball end of the first ball-bonded wire loop, and a wire section that is compressed into the ball end of the second ball-bonded wire loop and flattened.

2. The semiconductor package of claim 1,
wherein the ball end the first ball-bonded wire loop comprises a ball bump attached to one of the bond pad or the first lead and a stitch on the ball bump,
wherein the ball end of the second ball-bonded wire loop comprises a ball bump attached to the tail end of the first ball-bonded wire loop and a stitch on the ball bump of the second ball-bonded wire loop, and
wherein the tail end of the second ball-bonded wire loop is attached to the stitch and the ball bump of the first ball-bonded wire loop.

3. The semiconductor package of claim 1, wherein the at least two levels of stacked wire bond loops comprises:
a third ball-bonded wire loop stacked on the second ball-bonded wire loop, the third ball-bonded wire loop comprising a ball end attached to the tail end of the second ball-bonded wire loop, a tail end attached to the ball end of the second ball-bonded wire loop, and a wire section that is compressed into the ball end of the third ball-bonded wire loop and flattened.

4. The semiconductor package of claim 1, wherein the semiconductor die is a SiC or GaN die.

5. The semiconductor package of claim 4, wherein an outermost layer of the bond pad comprises copper, and wherein the first ball-bonded wire loop and the second ball-bonded wire loop both comprise copper.

6. The semiconductor package of claim 5, wherein the first ball-bonded wire loop and the second ball-bonded wire loop both have a diameter in a range of 25 μm to 75 μm.

7. The semiconductor package of claim 5, wherein the first ball-bonded wire loop has a first diameter, and wherein the second ball-bonded wire loop has a second diameter different than the first diameter.

8. The semiconductor package of claim 5, wherein the semiconductor die is attached to the substrate by lead-free solder.

9. The semiconductor package of claim 4, wherein the semiconductor die has an area less than 2 mm².

10. The semiconductor package of claim 9, wherein the semiconductor die has a current density greater than 4.5 A/mm².

11. A method of manufacturing a semiconductor package, the method comprising:
attaching a first side of a semiconductor die to a substrate, the semiconductor die having a bond pad at a second side of the semiconductor die opposite the first side;
forming a ball-bond interconnect structure that connects the bond pad to a first lead, the ball-bond interconnect structure comprising at least two levels of ball-bonded wire loops stacked on one another, and attached to one another at opposite ends of the stacked ball-bonded wire loops such that the at least two levels of stacked ball-bonded wire loops are electrically in parallel,
wherein forming the ball-bond interconnect structure comprises:
connecting a first ball-bonded wire loop between the bond pad and the first lead, the first ball-bonded wire loop comprising a ball end attached to one of the bond pad or the first lead, a tail end attached to the other one of the bond pad or the first lead, and a wire section that is compressed into the ball end of the first ball-bonded wire loop and flattened; and
vertically stacking a second ball-bonded wire loop on the first ball-bonded wire loop, the second ball-bonded wire loop comprising a ball end attached to the tail end of the first ball-bonded wire loop, a tail end attached to the ball end of the first ball-bonded wire loop, and a wire section that is compressed into the ball end of the second ball-bonded wire loop and flattened.

12. The method of claim 11,
wherein connecting the first ball-bonded wire loop between the bond pad and the first lead comprises:
attaching a first ball bump to one of the bond pad or the first lead;
forming a first stitch on the first ball bump;
attaching a first wire that extends from the first stitch to the other one of the bond pad or the first lead; and
severing the first wire to form the tail end of the first ball-bonded wire loop,
wherein vertically stacking the second ball-bonded wire loop on the first ball-bonded wire loop comprises:
attaching a second ball bump to the tail end of the first ball-bonded wire loop;
forming a second stitch on the second ball bump;
attaching a second wire that extends from the second stitch to the ball end of the first ball-bonded wire loop; and
severing the second wire to form the tail end of the second ball-bonded wire loop.

13. The method of claim 12, wherein attaching the second wire that extends from the second stitch of the second ball-bonded wire loop to the ball end of the first ball-bonded wire loop comprises:
in a longitudinal direction of the ball-bond interconnect structure, offsetting a center point of the tail end of the second ball-bonded wire loop from a center point of the first ball bump of the first ball-bonded wire loop.

14. The method of claim 11, wherein forming the ball-bond interconnect structure comprises:
stacking a third ball-bonded wire loop on the second ball-bonded wire loop, the third ball-bonded wire loop comprising a ball end attached to the tail end of the second ball-bonded wire loop, a tail end attached to the ball end of the second ball-bonded wire loop, and a wire section that is compressed into the ball end of the third ball-bonded wire loop and flattened.

15. The method of claim 11, wherein the semiconductor die is a SiC or GaN die.

16. The method of claim 15, wherein an outermost layer of the bond pad comprises copper, and wherein the first ball-bonded wire loop and the second ball-bonded wire loop both comprise copper.

17. The method of claim 16, wherein the first ball-bonded wire loop and the second ball-bonded wire loop both have a diameter in a range of 25 μm to 75 μm.

18. The method of claim 15, wherein attaching the first side of the semiconductor die to the substrate comprises:
soldering the first side of the semiconductor die to the substrate using lead-free solder.
